(19) United States
(12) Patent Application Publication
(10) Pub. No.: US 2018/0252949 A1
(43) Pub. Date: Sep. 6, 2018

(54) METHOD AND ARRANGEMENT FOR THE SECURE DISPLAY OF INFORMATION

(71) Applicant: siOPTICA GmbH, Jena (DE)

(72) Inventors: Markus KLIPPSTEIN, Jena (DE); Juergen SCHWARZ, Apolda (DE)

(21) Appl. No.: 15/759,176

(22) PCT Filed: Sep. 13, 2016
(86) PCT No.: PCT/EP2016/001538

§ 371 Date: May 7, 2018

(30) Foreign Application Priority Data
Sep. 14, 2015 (DE) 10 2015 011 933.8

(51) Int. Cl. G02F 1/13; G09G 3/3208; H01L 27/32; G02F 1/1347

(52) U.S. Cl. CPC G02F 1/1323; G09G 3/3208; G02B 2006/12097; G02F 1/13476; H01L 27/3232

(57) ABSTRACT

A method to operate a display screen D in at least two operating modes, B1 for a free viewing mode and B2 for a restricted viewing mode, comprising the following steps: arrangement of a switchable optical element immediately in front of a display screen as seen in a viewer's viewing direction, the said optical element ensuring switching between the at least two operating modes B1 and B2, presentation of an image content on the display screen, wherein the optical element contains a multitude of louvers, and wherein the optical effect of the louvers can be changed between transparent (B1) and luminous (B2) due to the fact that at least every twentieth louver contains triggerable layers that can be switched to be either transparent or brightly self-luminous.

### PRIORITY CLAIM

The present application is a National Phase entry of PCT Application No. PCT/EP2016/001538, filed Sep. 13, 2016, which claims priority from German Patent Application Number 102015011933.8, filed Sep. 14, 2015, the disclosures of which are hereby incorporated by reference herein in their entirety.

### FIELD OF THE INVENTION

In the development of flat-panel displays, the recent years have seen substantial efforts concentrated on increasing a viewer's viewing angle. Frequently, however, there are situations in which an excessive angular viewing range is a disadvantage, as, for example, during the entry of personal identification numbers (PINs) into the display screens of automated teller machines (ATMs). Also, applications enabling bank transactions to be conducted or other private particulars or sensitive data to be displayed are increasingly available for mobile devices such as tablet PCs, cell phones or even notebooks. For these purposes, the users of such devices need to have control of the viewing angle, e.g., to prevent any third persons situated within the angular viewing range from spying out sensitive data. On the other hand, many other applications, e.g., the viewing of still or moving images, usually call for a viewing angle that is as large as possible.

For all these applications, including sensitive and less sensitive ones, it is desirable to use one and the same display screen, not least to save costs. With ATMs as well as with PIN input devices at the checkout counters of stores and supermarkets, there is no need for the angular viewing range to be narrowed down so as to be observable only by the respective user standing in front of it; rather, during intervals in which the device is not used, the screen may display advertisements or other information that is intended to be seen by as many persons as possible.

Therefore, it is desirable to use one and the same device for both sensitive procedures that call for a narrow angular viewing range and less sensitive applications in which a wide angular viewing range is desirable, not least to reduce costs to the owners of such devices.

### DESCRIPTION OF PRIOR ART

In prior art, various approaches to this aim are known, which suffer from several disadvantages though.

Accessory sheets based on micro-louvers have long been known. They have already been used for small, mobile display screens to improve optical data protection. However, such foils cannot be switched over between a narrow and a wide viewing angle range; rather, they have to be applied and removed manually. Also, the films have to be carried separately from the display screen as long as they are not required for the respective application.

U.S. Pat. No. 6,765,550 B2 describes an improved privacy filter device on the basis of micro-louvers. Here, however, handling the filter involves its mechanical, i.e., manual attachment and removal, which is a disadvantage. Moreover, light loss in the protected mode is very high, so that this privacy filter can hardly be used in high-brightness environments. The additionally described built-in electric switching between a public and a private mode by means of polarization rotation gravely darkens the image, as this structure requires a distinctly greater number of optical layers. U.S. Pat. No. 6,211,930 B1 describes the use of a second LC display with privacy protection for automatic teller machines. Here, the rear illumination (backlight) is collimated in such a way that light can pass this arrangement only if an interposed diffusor is switched off. Here again, the technical complexity and costs involved are high. Because of the diffusor effect, brightness in the public mode is highly diminished.

In WO 2012/033583 A1, switching between free and restricted viewing is effected by the triggering of liquid crystals arranged between so-called “chromonic” layers. As in the film filters described above, the light loss is excessive here, and technical implementation is rather complex and expensive.

JP 2005-134678 A describes a display in which switching between a public and a private mode is effected by triggering liquid crystals. This solution is expensive, though; in addition it causes a great loss in brightness, as in the approaches described above.

The Applicant's WO 2015/121398 A1 describes a method of switching between a public and a private viewing mode, with the background illumination radiating light into unrestricted and a restricted angle, respectively. In front of this there is an LCD panel. Whereas this solution is attractive for LCD panels, it is unfit to offer a solution for self-luminous displays such as, e.g., OLEDs.

US 2014/0226093 A1 describes switching between a public and a private viewing mode by means of louvers filled with PDLC liquid crystals that can switch between a scattering and a transparent mode. This solution also works with self-luminous displays. As a drawback, PDLC crystals require relatively high alternating voltages of several tens of volts to switch to the transparent mode. The public mode, then, involves a permanent power consumption. Moreover, to obtain sufficiently strong scattering effects for the private mode, the PDLC crystals have to be quite some thickness, which results in an attenuation of the light transmitted in the transparent mode, so that, in this configuration, one has to reckon with visible structures on the screen that disturb the image appearance.

Further, US 2015/0138457 A1 discloses an autostereoscopic display screen and a method of using it. Here, privacy protection effects can be attained through definable vision zones (spatial angular ranges). For this purpose, a lens array is used, which projects light from an image display device into the space. Arranged between these two components there is another component for selective light shading and, thus, selecting the spatial angle ranges. The disadvantage here, in particular, is the diminished resolution due to the effects of the lenses.

US 2013/0050798 A1 discloses a switchable privacy filter and its manufacture. Here, an electrolyte fluid is filled in louver-like chambers to switch between a privacy mode and a free vision mode. Drawbacks are the high intricacy of fabrication and the light loss. US 2014/0327705 A1 describes a display screen that can be switched to a privacy mode by means of an optical component. For this purpose, the information radiated into a lateral spatial region is superimposed with scattered light and, thus, cannot be seen. However, this requires the optical component to be arranged behind the image display device, which is impracticable in many cases.

With the methods and arrangements known in prior art, the provision of a capability to switch between a private, protected mode with a restricted viewing angle range and a public, unprotected mode with a wide viewing angle range as a rule has the result that the brightness of the basic display screen is markedly decreased and/or the method is inapplicable to self-luminous types of display screens and/or one of the two modes, if not both, consume extra power. In addition, manufacture is, in most cases, technically complicated and, thus, expensive.

### DESCRIPTION OF THE INVENTION

Therefore, the problem underlying the invention is to develop a method and an arrangement for the secure presentation of information, with the arrangement and the method intended to be implementable in lot production at affordable cost. Added aims are to ensure that the brightness of the basic display screen is reduced but insignificantly or not at all, that the engineering approach is applicable also to self-luminous display types, and that, in either mode, any extra power consumption is negligible.

According to the invention, the problem is solved by a method for operating a display screen in at least two operating modes, i.e. B1 for a free viewing mode and B2 for a restricted viewing mode, comprising the following steps:
Arrangement of a switchable optical element immediately in front of a display screen as seen in a viewer's viewing direction, the said optical element ensuring switching between the at least two operating modes B1 and B2,
presentation of an image content on the display screen,
wherein the optical element contains a multitude of louvers, and wherein the optical effect of the louvers can be changed between transparent (B1) and luminous (B2) due to the fact that at least every twentieth louver contains triggerable layers that can be switched to be either transparent or brightly self-luminous.

It is possible, for example, that every second, third, fourth, fifth, tenth or preferably every single louver contains such triggerable layers that can be switched to be either transparent or brightly self-luminous.

In operating mode B2, “brightly self-luminous” means that the luminance on the triggerable layers corresponds to at least 30%, preferably more than 80%, or, with particular preference, above 100% of the luminance of a white image on the display screen.

The said triggerable layers may contain, e.g., transparent OLEDs, but also other layers that are switchable between transparent and self-luminous, e.g., electroluminescent layers.

In operating mode B1, the invention functions in such a way that all louvers are transparent and, therefore, do not obstruct the view from oblique viewing directions. In operating mode B2, when the louvers are luminous, they do obstruct the view of the image content displayed on the screen from viewing angles outside an angle α, due to superimposition of the light radiated laterally by the screen with light from the louvers, because the latter is almost exclusively visible when the viewer looks sideways.

Preferably, the louvers are arranged vertically, i.e. at an angle of 90 degrees relative to the screen surface. This angle substantially defines from what central angle an image can still be seen in the restricted viewing mode B2.

Furthermore, preferably those louvers that do not contain any of the said triggerable layers can contain passive means of light scattering instead, which, when illuminated by light from the triggerable layers, scatter this light and radiate it at least partially sideways in front of the screen, the haze of these passive light scattering means being smaller than 4%, preferably smaller than 2%, when measured in accordance with ASTM D1003. It is important that the passive Light scattering means are transparent when no light is incident on them, i.e. that they exhibit low haze, because it is only in this way that operating mode B1 can become possible.

Materials eligible for the passive light scattering means are, for example, titanium dioxide particles of a mean particle size of 150-500 nm in a concentration, related to the weight of the respective louver, of 0.01-300 wt.-ppm. Other configurations are possible, say, with particles of barium sulfate, silsesquioxane particles, cross-linked polystyrene particles or yet other kinds of particles. As a rule, the scattering particles are homogeneously distributed within the respective louvers.

Alternatively, such passive light scattering means may each consist of a matrix plastic A and, distributed therein, scattering particles of a polymerizate B, with the said scattering particles making up 0.01 to 3 wt.-% related to the matrix plastic A, and with the polymerizate B having a refractive index nD(B) that is higher than the refractive index nD(A) of the matrix plastic A by at least 0.002 units.

Furthermore, the passive light scattering means may contain at least 40 wt.-%, preferably at least 60 wt.-%, of polymethyl methacrylate related to their (partial) weight.

Moreover, any single louver itself may contain partial areas with triggerable layers and other partial areas that are provided with passive light scattering means.

The height of a louver may vary, e.g., between 50 μm and 500 μm, or be greater or smaller if necessary. This height depends on the desired viewing distance in operating mode B2. The louvers may have wall thicknesses between, e.g., 10 μm and 50 μm or greater. The average spacing between the center of one louver and the center of the nearest one is approximately equal to one time up to maximally ten times the order of magnitude of the louvers' wall thickness. Dimensioning is a matter of the experts' skill and, therefore, is not described in detail here.

Finally, it is also possible for two separate layers of louvers to be arranged in front of the display screen, crossed at an angle of preferably 90° relative to each other. Thereby, privacy protection in operating mode B2 is achieved simultaneously not only in two directions, e.g., left and right, but in four directions, i.e. left and right as well as top down and bottom up. This is particularly significant for payment terminal functions where suitable certification tests must be passed.

Suitable electronic circuitry for triggering the display screen and the switchable layers is provided, of course.

The display screen may be, e.g., an LCD screen, an OLED screen or an FED screen. Other configurations are possible, especially, but not exclusively such using other types of self-luminous displays.

Finally, some optically transparent material may be arranged as a filler between every two adjacent louvers. Such material may consist, e.g., of optical-quality casting resin, UV-curing material or acrylic glass. In this way, a robust construction will be achieved.

The problem of the invention is solved also by an arrangement for the secure display of image contents, which can be operated in at least two operating modes B1 for a free vision mode and B2 for a restricted vision mode, comprising:
a display screen,
a switchable optical element, which ensures switching between the at least two operating modes B1 and B2 and which is arranged directly in front of the display screen as seen in a viewer's viewing direction,
wherein the optical element contains a multitude of louvers, and wherein the optical effect of the louvers can be changed between transparent (B1) and luminous (B2) due to the fact that at least every twentieth louver contains triggerable layers that can be switched to be transparent or brightly self-luminous.

It is possible, for example, that every second, third, fourth, fifth, tenth or even each louver contains triggerable layers that can be switched to be transparent or brightly self-luminous. In operating mode B2, “brightly self-luminous” means that the luminance on the triggerable layers is at least 30%, preferably more than 80% or, with particular preference, more than 100% of the luminance of a white image on the screen.

The said triggerable layers may contain, e.g., transparent OLEDs or other layers that are switchable between transparent or self-luminous layers, such as, e.g., electroluminescent layers.

In operating mode B1, the invention functions in such a way that all louvers are transparent and, therefore, do not obstruct the view of the screen. In operating mode B2, when the louvers are luminous, they do obstruct the view of the image content displayed on the screen from viewing angles outside an angle α, due to superimposition of the light radiated laterally by the screen with light from the louvers, because the latter is almost exclusively visible when the viewer looks sideways.

Preferably, the louvers are arranged vertically, i.e. at an angle of 90 degrees relative to the screen surface. This angle substantially defines from what central angle an image can still be seen in the restricted viewing mode B2.

Preferably, the louvers are arranged on a transparent substrate (e.g., glass or PMMA). Furthermore, preferably those louvers that do not contain any of the said triggerable layers can contain passive means of light scattering instead, which, when illuminated by light from the triggerable layers, scatter this light and radiate it at least partially sideways in front of the screen, the haze of these passive light scattering means being smaller than 4%, preferably smaller than 2%, when measured in accordance with ASTM D1003. It is important that the passive light scattering means are transparent when no light is incident on them, i.e. that they exhibit low haze, because it is only in this way that operating mode B1 can become possible.

Materials eligible for the passive light scattering means are, for example, titanium dioxide particles of a mean particle size of 150-500 nm in a concentration, related to the weight of the respective louver, of 0.01-300 wt.-ppm. Other configurations are possible, say, with particles of barium sulfate, silsesquioxane particles, cross-linked polystyrene particles or yet other kinds of particles. As a rule, the scattering particles are homogeneously distributed within the respective louvers.

The passive light scattering means may also consist of a matrix plastic A and, distributed therein, scattering particles of a polymerizate B, with the said scattering particles making up 0.01 to 3 wt.-% related to the matrix plastic A, and the polymerizate B having a refractive index nD(B) that is higher than the refractive index nD(A) of the matrix plastic A by at least 0.002 units.

Furthermore, the passive light scattering means may contain at least 40 wt.-%, preferably at least 60 wt.-%, of polymethyl methacrylate related to their (partial) weight.

Moreover, any single louver itself may contain partial areas with triggerable layers and other partial areas that are provided with passive light scattering means.

The height of a louver may vary, e.g., between 50 μm and 500 μm, or be greater or smaller if necessary. This height depends on the desired viewing distance in operating mode B2. The louvers may have wall thicknesses between, e.g., 10 μm and 50 ρm or greater. The average spacing between the center of one louver and the center of the nearest one is approximately equal to one time up to maximally ten times the order of magnitude of the louvers' wall thickness. Other dimensions are possible as well. Dimensioning is a matter of the experts' skill and, therefore, is not described in detail here.

Finally, it is also possible for two separate layers of louvers to be arranged in front of the display screen, crossed at an angle of preferably 90° relative to each other. Thereby, privacy protection in operating mode B2 is achieved simultaneously not only in two directions, e.g., left and right, but in four directions, i.e. left and right as well as top down and bottom up. This is particularly significant for payment terminal functions where suitable certification tests must be passed.

Suitable electronic circuitry for triggering the display screen and the switchable layers is provided, of course.

The display screen may be, e.g., an LCD screen, an OLED screen or an FED screen. Other configurations are possible, especially, but not exclusively, such using other types of self-luminous displays.

Finally, some optically transparent material may be arranged as a filler between every two adjacent louvers. Such material may consist, e.g., of optical-quality casting resin, UV-curing material or acrylic glass. In this way, a robust construction will be achieved.

It is furthermore possible for the triggerable layers to radiate light from one of the large surfaces; this can be implemented, e.g., by transparent OLEDs. This would, in operating mode B2, provide privacy protection from one direction only, if so desired.

Finally, the louvers might be so configured that switching between operating modes B1 and B2 would only be achieved for part of the screen surface.

The invention also comprises the use of the invented method for operating a display screen or the use of a display screen of the invented type for entering confidential data in mode B2.

It is understood that the features mentioned before and those to be explained below are applicable not only in the combinations stated but also in other combinations or as stand-alone features without leaving the scope of the present invention.

### BRIEF DESCRIPTION OF THE DRAWINGS

Below, the invention and exemplary methods will be explained in more detail with reference to the accompanying drawings, which also show features essential to the invention, among others, and in which

FIG. 1 shows an implementation of the invented method in mode B1,

FIG. 2 shows an implementation of the invented method in mode B2, and

FIG. 3 shows an implementation of the invented method in mode B2, here with a different configuration of the louvers.

All drawings are merely schematic and not to scale.

### DETAILED DESCRIPTION OF THE INVENTION

The invented method of operating a display screen 1 in at least two operating modes, viz. B1 for a free viewing mode and B2 for a restricted viewing mode, comprise the following steps as described hereinbefore:
Arrangement of a switchable optical element 3 immediately in front of a display screen 1 as seen in a viewer's 5 viewing direction, the said optical element ensuring switching between the at least two operating modes B1 and B2,
presentation of image content on the display screen 1,
wherein the optical element 3 contains a multitude of louvers 4, and wherein the optical effect of the louvers 4 can be changed between transparent (B1) and luminous (B2) in such a way that at least every twentieth louver 4 contains triggerable layers 2 that can be switched to be either transparent or brightly self-luminous.

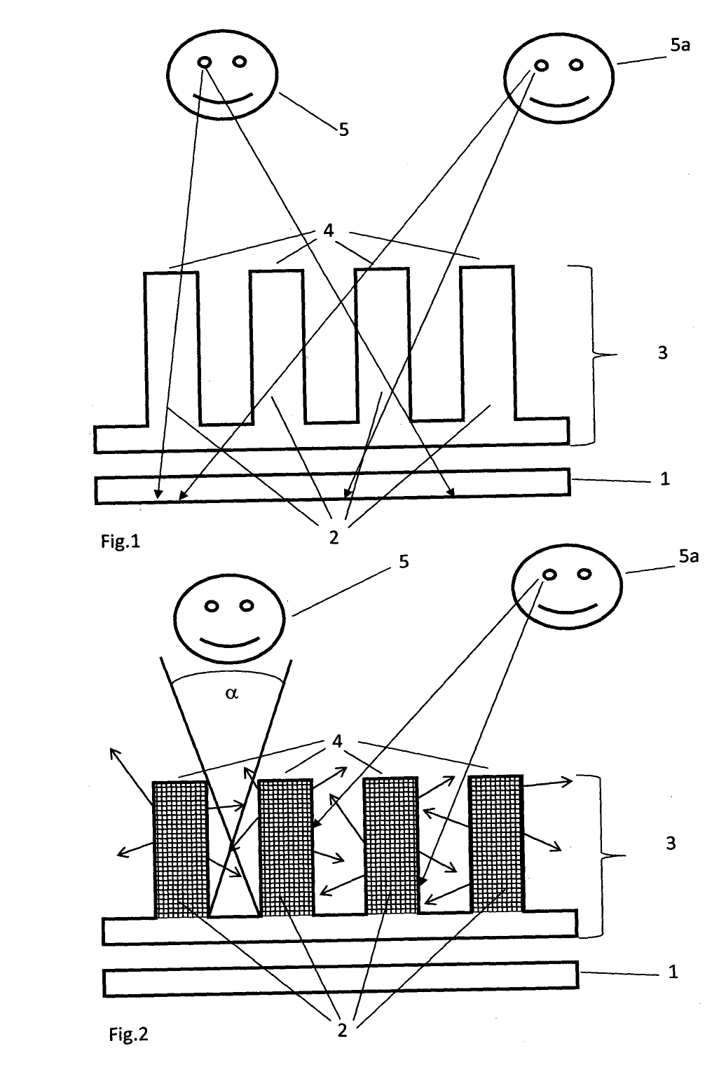

In the example illustrated by FIG. 1, each louver 4 contains triggerable layers 2, which can be switched to be either transparent or brightly self-luminous. Here, the said triggerable layers 2 are implemented, e.g., by transparent OLEDs, so that these louvers 4 can be switched between a transparent and a self-luminous state.

FIG. 1 shows an implementation of this invented method in mode B1. In this operating mode B1, the invention functions in such a way that the louvers 4 are all transparent (because the triggerable layers 2 are switched to be transparent) and therefore do not obstruct the view of the display screen 1 for any of the viewers 5 and 5a viewing from any directions.

FIG. 2 shows an implementation of the invented method in mode B2. In this operating mode B2, when the louvers 4 emit light (because the triggerable layers 2 are in the self-luminous state), they obstruct the view of the image content shown on display screen 1 for a viewer 5a at a viewing angle outside a in that the light radiated laterally by the display screen 1 is superimposed with light emitted by the louvers 4 (see the arrows extending from the louvers 4 in FIG. 2), which is almost exclusively visible if looked at from the side, e.g. from the viewing position of viewer 5a. For viewer 5, viewing is not restricted as long as he/she remains within angle α. In FIG. 1 this can at best be hinted at, since, with dimensions in their correct relation, viewer 5 would have to be drawn markedly further above the display screen 1, for which the illustration lacks sufficient space.

Preferably, the louvers 4 are arranged vertically, i.e. at an angle of 90 degrees relative to the surface of the display screen 1. This angle substantially defines from what central angle an image can still be seen in the restricted viewing mode B2.

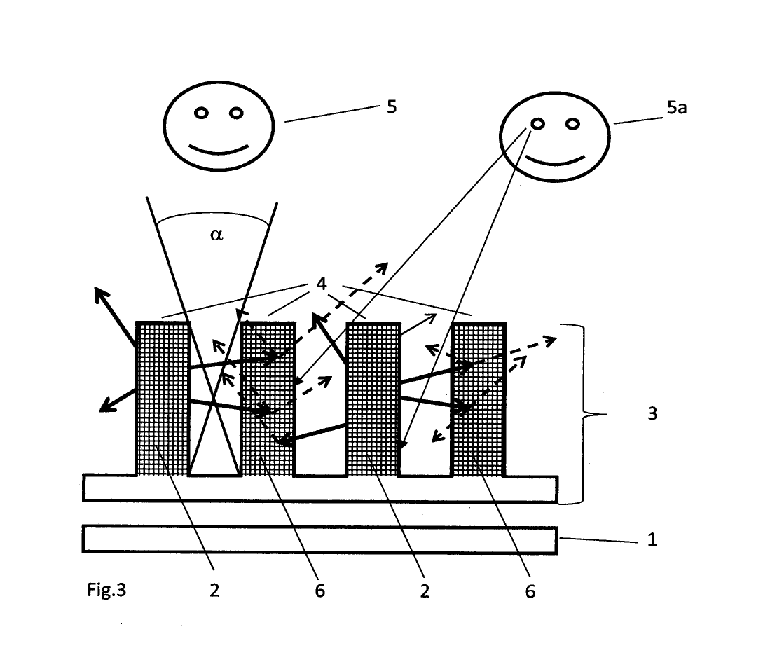

FIG. 3 shows a configuration in operating mode B2 in which only every other louver 4 contains triggerable layers 2 that can be switched to be transparent or brightly self-luminous. The remaining louvers 4 (those in between the ones just mentioned), which contain none of the said triggerable layers 2, rather contain passive light scattering means 6, which, when illuminated with light (see the solid arrowed lines in FIG. 3) emitted by the triggerable layers 2, will scatter this light and at least partially radiate it laterally to the front of the display screen 1 (see the dashed arrowed lines in FIG. 3), with the haze of these passive light scattering means 6 is smaller than 4% but preferably smaller than 2% as measured according to ASTM D1003. The entirety of all louvers 4, then, effects privacy protection as described above, as the light coming from the display screen is, at lateral angles, superimposed with that coming from the louvers in such a way that the image content displayed cannot be seen by viewer 5a. Viewer 5, on the other hand, can see the image almost unimpaired, since no, or almost no light is radiated normal to the display screen 1. In addition, the louvers 4 can, on their sides facing the viewer 5, contain opaque lines that make the louvers 4 opaque from the viewing direction and thus prevent light exit in the viewing direction.

It is important that the passive light scattering means 6 are transparent whenever no light is incident on them, i.e., that they exhibit low haze, because only then operating mode B1 is possible to happen.

Materials eligible for the passive light scattering means 6 are, for example, titanium dioxide particles of a mean particle size of 150-500 nm in a concentration, related to the weight of the respective louver, of 0.01-300 wt.-ppm. Other configurations are possible, say, with particles of barium sulfate, silsesquioxane particles or cross-linked polystyrene particles or yet other kinds of particles. As a rule, the scattering particles are homogeneously distributed within the respective louvers 4.

Furthermore, the passive light scattering means 6 may contain at least 40 wt.-%, preferably at least 60 wt.-%, of polymethyl methacrylate related to their (partial) weight.

The height of a louver 4 may vary, e.g., between 50 m and 500 m, or be greater or smaller if necessary. This height depends on the desired viewing distance in operating mode B2. The louvers 4 may have wall thicknesses between, e.g., 10 μm and 50 μm or greater. The average spacing between the center of one louver and the center of the nearest one is approximately equal to one time up to maximally ten times the order of magnitude of the louvers' wall thickness. Other dimensions are possible as well. Dimensioning is a matter of the experts' skill and, therefore, is not described in detail here.

Suitable electronic circuitry for triggering the display screen 1 and the switchable layers 2 is provided, of course.

The display screen 1 may be, e.g., an LCD screen, an OLED screen or an FED screen. Other configurations are possible, especially, but not exclusively, such using other types of self-luminous displays. Finally, some optically transparent material may be arranged as a filler between every two adjacent louvers 4. Such material may consist, e.g., of optical-quality casting resin, UV-curing material or acrylic glass. In this way, a robust construction will be achieved.

Analogously, the above explanations of the drawings FIG. 1 through FIG. 3 are also applicable to the invented arrangement. To avoid redundancy they are not repeated here.

The invented method and the invented arrangement described above make it possible, if and when desired, to present security-relevant information within a small angular viewing range only, so that it can only be seen by the person addressed, whereas information that is not security-relevant can be presented with the full resolution of the display screen in such a way that it can be seen from a wide angular viewing range and, thus, by third persons such as bystanders.

The invention solves the problem outlined at the start. It proposes a method and an arrangement for the secure display of information, which can be implemented in lot production at reasonable cost. As added advantages, the said method and arrangement hardly reduce the brightness of the base display screen, if at all; the technical approach is also applicable for self-luminous display types, and the extra power consumed in both operating modes and with all configurations of the invention is negligible. Switching between operating modes B1 and B2, too, requires a very small amount of power.

1. A method to operate a display screen in at least two operating modes, a free-viewing mode and a restricted-viewing mode, comprising the following steps:
arranging, immediately in front of a display screen in a viewing direction of a viewer, a switchable optical element that enables switching between the at least two operating modes, the optical element including a plurality of louvers, and at least every twentieth louver of the plurality of louvers includes a triggerable layer configured to be switched between a transparent state or a self-luminous state, thereby creating an optical effect;
displaying an image content on the display screen,
switching between the free-viewing mode and the restricted-viewing mode by causing the triggerable layer to be switched between the transparent state and the self-luminous state.

2. The method as claimed in claim 1, wherein the triggerable layer contains transparent OLEDs and/or an electroluminescent layer.

3. The method as claimed in claim, wherein those louvers which do not contain a triggerable layers contain passive light scattering portions, which, when illuminated with light from the triggerable layers, scatter this light and radiate it at least partially sideways in front of the display screen, with the haze of these passive light scattering portions being less than 4%, preferably less than 2%, measured in accordance with ASTM D1003.

4. The method as claimed in claim 1, wherein the display screen is an LCD screen, an OLED screen or an FED screen.

5. The method as claimed in claim 1, wherein optically transparent material as a filler is disposed between every two adjacent louvers, this material comprising optical casting resin, UV-curing material or acrylic glass.

6. A system for the secure display of image contents, which can be operated in at least two operating modes, a free-viewing mode and a restricted-viewing mode, comprising:
a display screen,
a switchable optical element that enables switching between the at least two operating modes and is arranged immediately in front of a display screen in a viewing direction of a viewer,
wherein the optical element contains a multitude of louvers, wherein the optical effect of the louvers can be altered between transparent and luminous due to the fact that at least every twentieth louver contains triggerable layers that can be switched to be either transparent or brightly self-luminous.

7. The arrangement as claimed in claim 6, wherein the triggerable layer contains transparent OLEDs and/or an electroluminescent layer.

8. The arrangement as claimed in claim 6, wherein those louvers which do not contain a triggerable layers contain passive light scattering portions, which, when illuminated with light from the triggerable layers, scatter this light and radiate it at least partially sideways in front of the display screen, with the haze of these passive light portion being less than 4%, preferably less than 2%, measured in accordance with ASTM D1003.

9. The system as claimed in claim 6, wherein the display screen is an LCD screen, an OLED screen or an FED screen.

10. (canceled)

11. The method of claim 1, further comprising switching to the restricted-viewing mode, and entering confidential data.
